(19) United States
(12) Patent Application Publication
(10) Pub. No.: US 2021/0257174 A1
(43) Pub. Date: Aug. 19, 2021

(54) CHIP-TYPE FUSE WITH A METAL WIRE TYPE FUSIBLE ELEMENT AND MANUFACTURING METHOD FOR THE SAME

(71) Applicant: Conquer Electronics Co.,Ltd., New Taipei City (TW)

(72) Inventors: Hung-Chih CHIU, New Taipei City (TW); Po-Shuo CHIU, New Taipei City (TW)

(21) Appl. No.: 16/811,539

(22) Filed: Mar. 6, 2020

(30) Foreign Application Priority Data
Feb. 13, 2020 (TW) 109104597

(51) Int. Cl. H01H 85/04; H05K 1/18; H05K 1/11; H05K 3/28; H05K 3/00; H05K 3/40; H01H 69/02

(52) U.S. Cl. CPC H01H 85/04; H05K 1/181; H05K 1/111; H05K 2201/10181; H05K 3/0044; H05K 3/4007; H01H 69/022; H05K 3/28

(57) ABSTRACT

A chip-type fuse has a substrate. Two pads are disposed over a first side of the substrate. At least one fusible element is disposed over the first side of the substrate and electrically connects to the pads. A protective layer covers the first side of the substrate and the fusible element. The fusible element has a cross-section that is substantially circular, so the time durations for heat conduction from the center to points on the radial edge at the cross-section of the fusible element are almost equal. Thus, the fusible element can be uniformly heated. Therefore, when the circuit is overheated, the blow of the fusible element is uniform, which may effectively interrupt the circuit and protect the circuit.

### CROSS-REFERENCE TO RELATED APPLICATIONS

This application is based upon and claims priority under 35 U.S.C. 119 from Taiwan Patent Application No. 109104597 filed on Feb. 13, 2020, which is hereby specifically incorporated herein by this reference thereto.

### BACKGROUND OF THE INVENTION

### 1. Field of the Invention

The present invention relates to a chip-type fuse and a manufacturing method for the same.

### 2. Description of the Prior Arts

Chip-type fuses have characteristics of small size, lightweight, and good surge current resistance so that they are currently widely used in various electronic devices. In prior art, the chip-type fuses have a ceramic substrate with a fusible element formed thereon. Generally, there are two ways to form the fusible element on a ceramic substrate. One way is the printing method. The fusible element is printed on the ceramic substrate and from a thick-film fusible element. The other way is sputtering. The fusible element is sputter-formed on a ceramic substrate and forms a thin-film fusible element.

However, whether the fusible element is formed by printing or sputtering, its cross-sectional shape is non-uniform. When the fusible element is blown, the time durations that heat transfers from the center to each point are different because the distances from the center to points on the radial edge at the cross-section of the fusible element are different. Different heat conduction time durations lead to the phenomenon of uneven melting area, which makes the effect of instantaneous melting worse.

### SUMMARY OF THE INVENTION

In view of the above, the present invention is directed to a chip-type fuse which can improve the problems of surge currents and uneven melting.

To achieve the above objects, the present invention provides a chip-type fuse, including a substrate having a first side surface; two solder pads spaced apart from each other, disposed over the first side surface of the substrate; at least one fusible element disposed over the first side surface of the substrate and electrically connected to the solder pads, wherein each of the at least one fusible element is substantially circular in radial cross-section; a protective layer covering the first side surface of the substrate, the at least one fusible element and the pads; and two terminal electrodes disposed at the ends of the at least one fusible element, wherein the terminal electrodes are electrically connected to the ends of the at least one fusible element, respectively.

To achieve the above objects, the present invention provides a method of manufacturing a chip-type fuse, including providing a substrate sheet, which has a plurality of substrates pre-marked and arranged in a matrix; forming a plurality of solder pads over the substrate sheet, wherein the solder pads are formed at the ends opposite the side surface of the substrates; disposing a plurality of fusible wires over the substrate sheet, wherein each of the fusible wires is straddled over two solder pads and connecting them, wherein each of the substrates corresponds to at least one fusible wire, wherein each of the fusible wires has a cross-section substantially circular; disposing a protective layer over the substrate sheet, wherein the protective layer covers the first side surfaces, the fusible wires, and the substrates; dicing the substrate sheet to separate the plurality of the substrates and the fusible wires thereon; forming terminal electrodes over the substrates, wherein the terminal electrodes are disposed at two ends of each of the substrates and electrically connected to the fusible elements over the substrates.

The present invention includes at least the advantages described below. Because the fusible element has a cross-section substantially circular, the distance from a center to points over the radial edge at each cross-section of the fusible element is almost equal. Thus, the time durations that heat transfers from the center to each point over the radial edge are substantially equal, and fuses are blown uniformly.

### BRIEF DESCRIPTION OF THE DRAWINGS

FIG. 1 is a 3-D scheme of a first embodiment of a chip-type fuse in accordance with the present invention;

FIG. 2A is a cross-sectional view of the chip-type fuse in FIG. 1;

FIG. 2B is an enlarged scheme of the dotted area shown in FIG. 2A;

FIG. 3 is an end view of the chip-type fuse in FIG. 1;

FIG. 4A is a cross-sectional view of a second embodiment of a chip-type fuse in accordance with the present invention;

FIG. 4B is a cross-sectional view of a third embodiment of a chip-type fuse in accordance with the present invention;

FIG. 5A is a flow chart of a first embodiment of a method of manufacturing a chip-type fuse in accordance with the present invention;

FIG. 5B shows a flow chart of a second embodiment of a method of manufacturing a chip-type fuse in accordance with present invention;

FIG. 5C shows a flow chart of a third embodiment of a method of manufacturing a chip-type fuse in accordance with the present invention; and

FIGS. 6-8B is an illustrative scheme that shows a partially finished chip-type fuse in portions of steps manufactured by the method according to the present invention.

### DETAILED DESCRIPTION OF THE EMBODIMENTS

It is to be understood that the following disclosure provides many different embodiments, or examples, for implementing different features of the disclosure. Specific examples of components and arrangements are described below to simplify the present disclosure. These are, of course, merely examples and are not intended to be limiting. Various features may be arbitrarily drawn in different scales for the sake of simplicity and clarity. That is, the elements shown in the figure are not presented in actual numbers, actual shapes, actual dimensions, and actual proportions. The detailed components layout may be more complicated in reality.

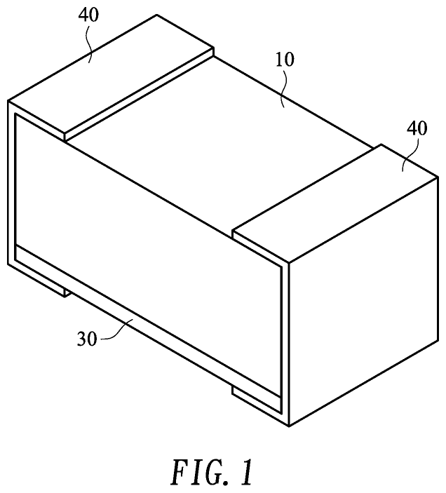

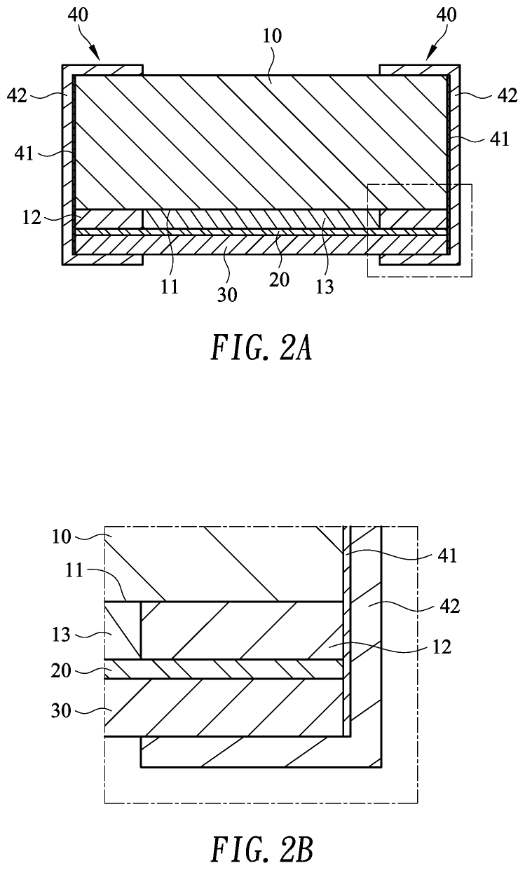

With reference to FIG. 1 and FIG. 2A, a chip-type fuse according to the present invention includes a substrate 10, at least one fusible element 20, a protective layer 30, and two terminal electrodes 40.

The substrate 10 is made of a temperature-resistant insulating material such as ceramic, glass, or printed circuit board (PCB), but not limited thereto. Two solder pads 12 are disposed on a first side surface 11 of the substrate 10. The solder pads 12 have an interval between them.

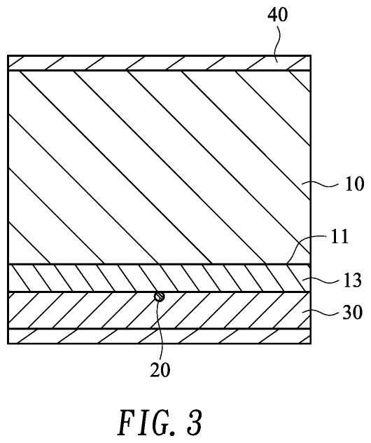

The at lease one fusible element 20 is disposed over the first side surface 11 of the substrate 10. The two ends of the fusible element 20 are welded to the pads 12, respectively. With reference to FIG. 3, the fusible element 20 is circular or substantially circular in radial cross-section. The fusible element 20 is made of copper, silver, tin, or an alloy thereof, but not limited thereto. In an embodiment, a plurality of fusible elements 20 are disposed on the first side surface 11 of the substrate 10, are spaced apart from each other and connect in parallel through the bonding pads 12.

The protective layer 30 covers the first side surface 11 of the substrate 10, the fusible elements 20 and the solder pads 12. In an embodiment, the protective layer 30 is made of a temperature-resistant insulating material, such as silicone, but not limited thereto.

With reference to FIG. 1, FIG. 2A, and FIG. 2B, the terminal electrodes 40 are disposed at two ends of the substrate 10, respectively. Each of the terminal electrodes 40 is electrically connected to the fusible element 20. The terminal electrodes 40 are made of conductive materials such as a silver layer 41 with a conductive material layer 42 (such as nickel or tin), but not limited thereto.

Because the fusible element 20 is circular or substantially circular in radial cross section, the distance from a center to points on the radial edge at each cross-section of the fusible element 20 is almost equal. Thus, the time durations that heat transfers from the center to each point on the radial edge are substantially equal, and the time difference that the heat transfers from the center to each point on the radial edge can be minimized. When the current rises abnormally and exceeds the rated current, the fusible element 20 is overheated and blown. The fusible element 20 is uniformly blown because time durations that heat transfers from the center to each point on the radial edge at each cross-section of the fusible element 20 are almost equal. Then the circuit is interrupted instantly.

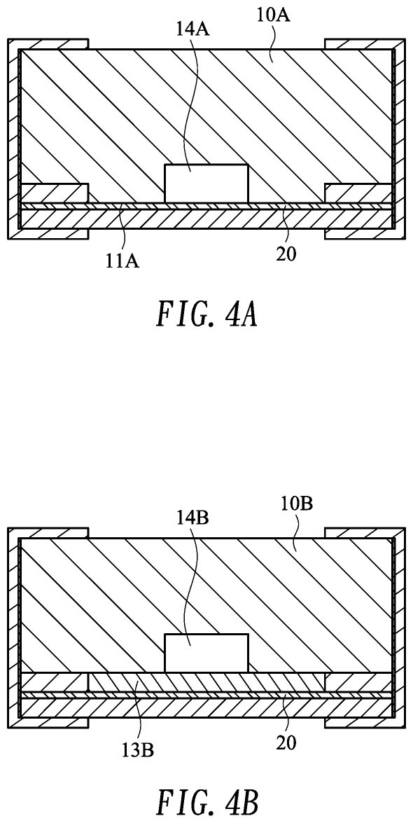

In an embodiment, a heat insulation unit is disposed on the substrate 10 and correspond to the position of the fusible element 20. The heat insulation unit is disposed between the fusible element 20 and the substrate 10. The heat insulation unit can confine the heat to the fusible element 20 (or can limit the heat to stay over the fusible element 20). Thus, the problem of that the fusible element 20 cannot effectively show the circuit overheating, resulting from excessive heat dissipating from the fusible element 20 through the substrate 10, can be avoided. In an embodiment, as shown in FIG. 2A, the heat insulation unit is a heat insulation layer 13. In an embodiment, as shown in FIG. 4A, the heat insulation unit is a groove 14A, and the groove 14A is formed on the first side surface 11A of the substrate 10A. With the disposition of the heat insulation layer 13 or the groove 14A, the fusible element 20 can be separated from the substrate 10, or at least the area where the fusible element 20 is in contact with the substrate 10 can be reduced. As compared to a solid substance (such as the substrate itself or the heat insulation unit), the air is a bad thermal conducting medium. Thus, better thermal insulation can be achieved. Also, the groove 14A located between the fusible element 20 and the substrates 10A can provide a space for the fusible element 20 to retract when the fusible element 20 is blown. In another embodiment, as shown in FIG. 4B, the heat insulation unit includes a groove 14B and a heat insulation layer 13B. The heat insulation layer 13B is located between the groove 14B and the fusible element 20 for increasing the insulation effect.

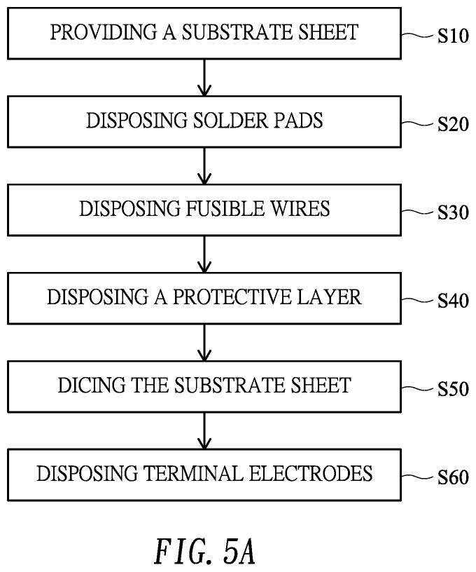

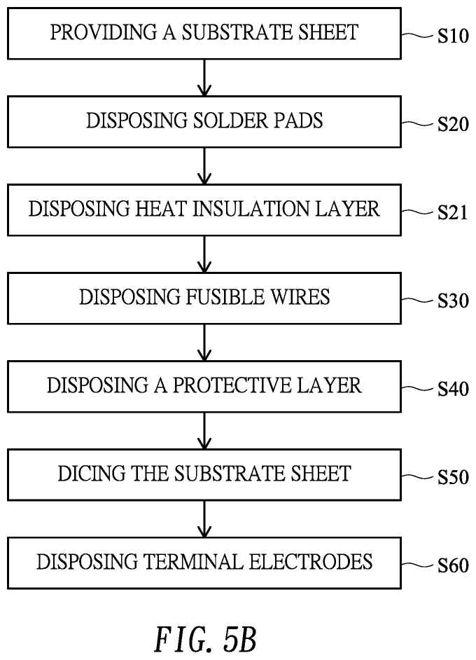

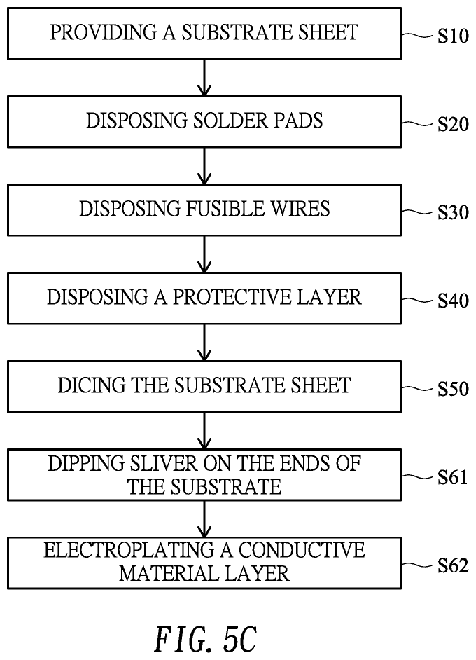

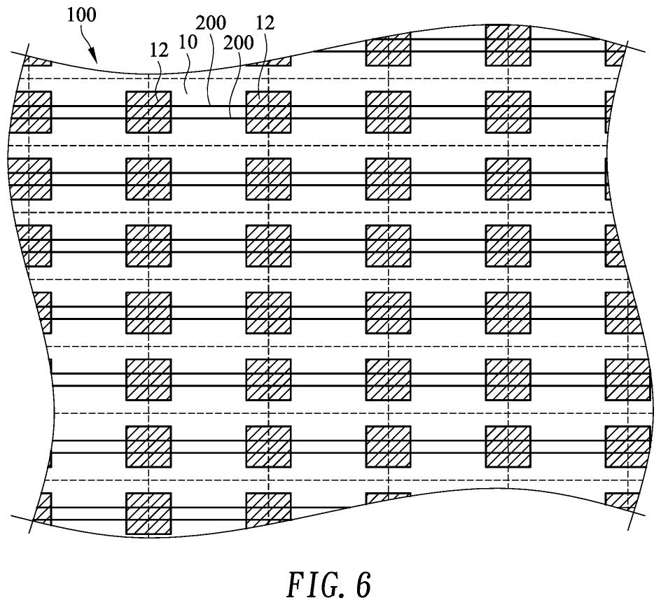

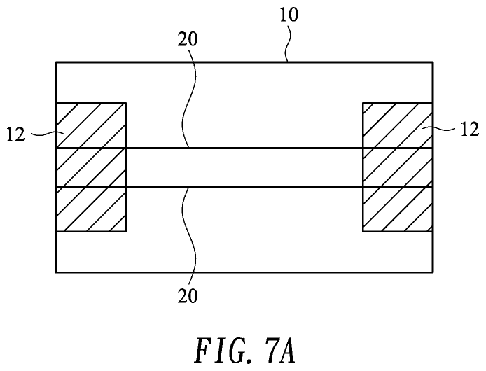

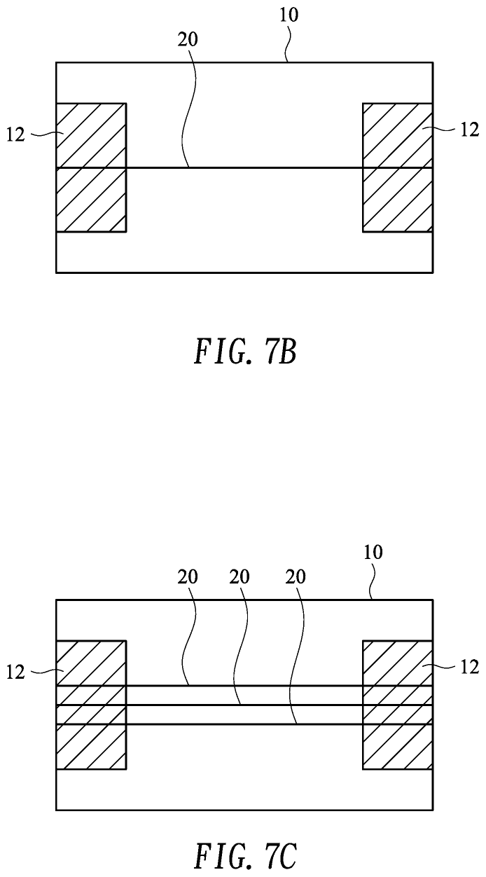

With reference to FIG. 5A, a method for manufacturing a wafer fuse in accordance with the present invention is described. A substrate sheet 100 is provided (S10) (as shown in FIG. 6). The substrate sheet 100 has a plurality of substrates 10 pre-marked and arranged in a matrix. Then, for each substrate 10, two solder pads 12 are disposed at the ends of the first side surface of each substrate 10 over the substrate sheet 100 (S20). Then, a plurality of fusible wires 200 are disposed on the substrate sheet 100 (S30). Each fusible wire 200 is bridged over the corresponding solder pads 12. In one embodiment, the fusible wires 200 are fixed to the corresponding solder pads 12 by welding. Each substrate 10 corresponds to at least one of the fusible wires 200, and the fusible wires 200 are not in contact with each other. In one embodiment, the fusible wires 200 are arranged in parallel. Then, a protective layer 30 is disposed on the substrate sheet 100 to cover the first side surfaces of the substrates 10 and the fusible wires 20 (S40). Then, the substrate sheet 100 is diced to separate the substrates 10 and the fusible elements 20 thereon (S50) (as shown in FIG. 7). Finally, terminal electrodes 40 are formed at the ends of the substrate 10 and electrically connected to the end portions of the fusible elements 20 (S60) (as shown FIG. 2A).

In this embodiment, because the material of the substrate sheet 100 is non-wetting, the solder is confined in the areas of solder pads 12, and the distance between the solder joints at the two ends of the fusible element 20 is thus be fixed. Since the electrical resistance of the chip type fuse as described is relevant to the distance between the solder joints at the two ends of the fusible element 20, the consistency of electrical resistances of the chip type fuses is improved, and a large shift of electrical resistances resulting from the position shifting of the solder joints is avoided. The quality of the chip type fuses as described is ensured because the electrical properties of the chip type fuses as described are kept consistent.

In this embodiment, two fusible elements 20 are disposed on a corresponding substrate 10 (as shown in FIG. 7A), but not limited thereto. As shown in FIG. 7B, a single fusible element 20 may be disposed on a corresponding substrate 10. As shown in FIG. 7C, multiple fusible elements 20 may be disposed on a corresponding substrate 10.

Furthermore, With reference to FIG. 5B, a manufacturing method according to another embodiment of the present invention is provided. After the step S20, a heat insulation unit is disposed on the substrate sheet 100 (S21) before disposing of the fusible wires 200 as described at the step S30.

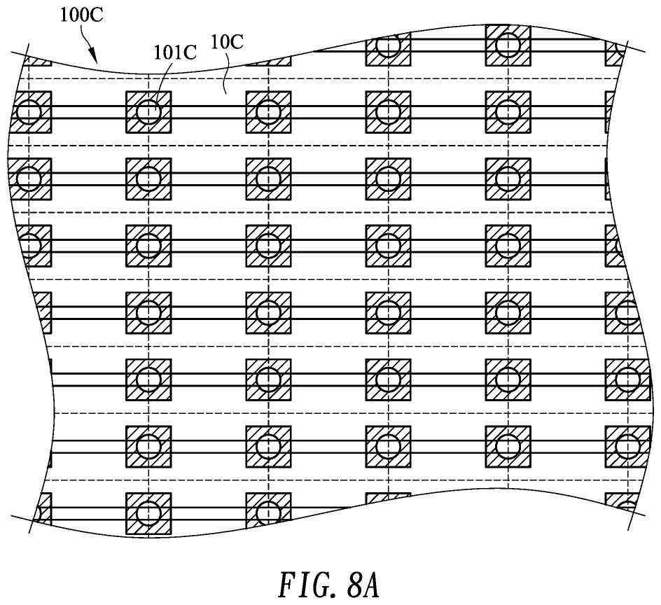

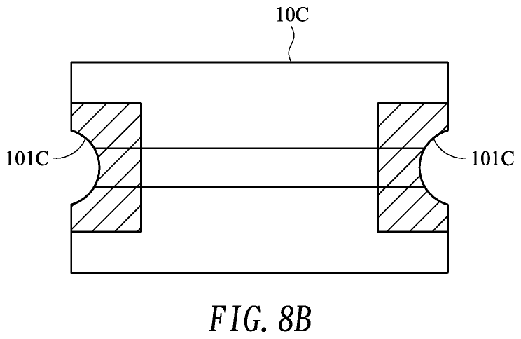

Furthermore, the formation of the terminal electrodes 40 can be varied by the shape of the substrate 10 and the pre-processing step. In one embodiment, as shown in FIG. 7A, the two ends of the substrate 10 are flat (With reference to FIGS. 5C, 2A and 2B). After the step S50, the two ends of the substrate 10 are dipped in silver for forming silver layers 41 (S61). The silver layers 41 are electrically connected to the ends of the fusible element 20. Conductive material layers 42 are then electroplated over the silver layers 41 (S62), and the terminal electrodes 40 are formed. In another embodiment, as shown in FIGS. 8A and 8B, conductive holes 101C are formed on the substrate sheet 100C at where the substrates 10C connect to each other in advance, and the walls of the conductive holes 101C are coated with a conductive material such as silver. The conductive material on the walls of the holes 101C is electrically connected to the ends of the fusible element 20. As shown in FIG. 5A, after the step S50, a conductive material layer is electroplated over the conductive holes 101C at both ends of the substrate 10C, and the terminal electrodes are formed (S60). Therefore, in the embodiment in which the conductive holes 101C are provided over the substrate sheet 100C in advance, the manufacturing steps can be simplified, and the step of forming a silver layer by dipping silver can be omitted.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

1. A chip-type fuse, comprising:
a substrate having a first side surface;
two solder pads, spaced apart from each other, and disposed on the first side surface of the substrate;
at least one fusible element disposed on the first side surface of the substrate and electrically connected to the solder pads, wherein each of the at least one fusible element is substantially circular in radial cross section;
a protective layer covering the first side surface of the substrate, the at least one fusible element and the pads; and
two terminal electrodes disposed at the ends of the at least one fusible element, wherein the terminal electrodes are electrically connected to the ends of the at least one fusible element, respectively.

2. The chip type fuse as claimed in claim 1, wherein each of the at least one fusible element includes a plurality of fusible elements connected in parallel through the solder pads.

3. The chip type fuse as claimed in claim 1 further comprising a heat insulation unit disposed between the at least one fusible element and the substrate.

4. The chip type fuse as claimed in claim 3, wherein the heat insulation unit comprises a heat insulation layer.

5. The chip type fuse as claimed in claim 3, wherein the heat insulation unit is a groove formed on the first side surface of the substrate.

6. The chip type fuse as claimed in claim 1, wherein each of terminal electrodes comprises a silver layer and a conductive material layer formed on the silver layer, wherein the silver layers of the terminal electrodes are disposed at the two ends of the substrate and electrically connected to the ends of the at least one fusible element.

7. The chip type fuse as claimed in claim 2, wherein each of terminal electrodes comprises a silver layer and a conductive material layer formed on the silver layer, wherein the silver layers of the terminal electrodes are disposed at the two ends of the substrate and electrically connected to the ends of the fusible elements.

8. The chip type fuse as claimed in claim 1 further comprising conductive holes formed on the surfaces at the ends of the substrate and a conductive material coated on walls of the conductive holes, wherein the conductive material is electrically connected to the ends of the at least one fusible element, wherein each of the terminal electrodes comprises a conductive material layer formed on the conductive material on the walls of the conductive holes.

9. The chip type fuse as claimed in claim 2 further comprising conductive holes formed on the surfaces at the ends of the substrate and a conductive material coated on walls of the conductive holes, wherein the conductive material is electrically connected to the ends of the fusible elements, wherein each of the terminal electrodes comprises a conductive material layer formed on the conductive material on the walls of the conductive holes.

10. A method of manufacturing a chip-type fuse, comprising steps of:
providing a substrate sheet, which has a plurality of substrates pre-marked pre marked and arranged in a matrix;
forming a plurality of solder pads on the substrate sheet, wherein the solder pads are formed at the ends of the side surface of the substrates;
disposing a plurality of fusible wires over the substrate sheet, wherein each of the fusible wires is bridged over the solder pads, wherein each of the substrates corresponds to at least one of the fusible wires, wherein each of the fusible wires substantially circular in radial cross section;
disposing a protective layer on the substrate sheet, wherein the protective layer covers the first side surfaces of the substrates and the fusible wires;
dicing the substrate sheet to separate the plurality of the substrates and the fusible wires thereon;
forming terminal electrodes over the substrates, wherein the terminal electrodes are disposed at two ends of each of the substrates and electrically connected to the fusible elements on the substrates.

11. The method as claimed in claim 10, wherein the step of disposing terminal electrodes on the substrates comprises steps of:
dipping sliver on the two ends of the substrates for forming silver layers, wherein the sliver layers are electrically connected to the fusible elements; and
forming conductive material layers on the silver layers.

12. The method as claimed in claim 10, wherein:
the step of providing the substrate sheet comprises providing a substrate sheet that has conductive holes formed at where the substrates connect to each other and a conductive material coated on walls of conductive holes; and
the step of forming terminal electrodes comprises forming conductive material layers on the walls of the conductive holes in order to form the terminal electrodes.
